(19) United States
(12) Patent Application Publication
(10) Pub. No.: US 2007/0249138 A1
(43) Pub. Date: Oct. 25, 2007

(54) Buried dielectric slab structure for CMOS imager

(75) Inventors: Jiutao Li, Boise, ID (US); David Wells, Boise, ID (US)

Correspondence Address: DICKSTEIN SHAPIRO LLP, 1825 EYE STREET, NW, WASHINGTON, DC, 20006, US

(73) Assignee: MICRON TECHNOLOGY, INC.

(21) Appl. No.: 11/408,981

(22) Filed: Apr. 24, 2006

(51) Int. Cl. H01L 21/8238; H01L 29/80; H01L 21/76

(52) U.S. Cl. 438/424; 438/199; 257/274

(57) ABSTRACT

A substrate structure, and method of forming the structure, are provided. The structure, which may be used for a CMOS imager device, is provided with a buried dielectric structure. Recesses are formed on a semiconductor substrate, e.g., silicon, and a dielectric material is used to fill the recesses. A layer of semiconductor material, e.g., silicon, is then formed over the surface of the substrate material and dielectric-filled trenches.

### FIELD OF THE INVENTION

The invention relates to the field of semiconductors, and particularly, semiconductor substrate wafers.

### BACKGROUND OF THE INVENTION

Epitaxial silicon (epi-silicon) substrate wafers are widely used in solid state imager manufacturing because they provide good dark current performance.

FIG. 1 illustrates a cross-section of a semiconductor substrate 10. In conventional imager fabrication, the silicon substrate 10 is a thin layer of silicon upon which an epitaxial silicon layer 15 is formed. The epitaxial silicon grown on wafers is grown over a clean, flat wafer. Imager formation is conducted on the epitaxial layer 15. Not using such a starting substrate may cause crystal lattice defects which cause leakage or dark current in CMOS imagers. These crystals are typically caused by both non-planar geometry and use of different materials.

It would be useful to create buried dielectric structures below the imager to minimize such crystal defects, but doing so typically causes performance degradation. Therefore, an epitaxial silicon substrate with buried dielectric structures (as also described in U.S. patent application Ser. No. 11/076,774 to Tang et al.) but with low silicon crystal defects are desired and disclosed here.

### BRIEF DESCRIPTION OF THE DRAWINGS

The invention is described in detail below in connection with exemplary embodiments in connection with the accompanying drawings in which:

FIG. 1 illustrates a cross-section of a semiconductor substrate at an initial stage of conventional imager fabrication;

FIG. 2a illustrates a cross-section of the exemplary embodiment at a stage of fabrication subsequent to FIG. 1;

FIG. 2b illustrates a cross-section of another embodiment of the present invention at a stage of fabrication subsequent to FIG. 1;

FIG. 2c illustrates a cross-section of another embodiment of the present invention at a stage of fabrication subsequent to FIG. 1;

FIG. 2d illustrates an isometric view of an embodiment of the present invention at the stage of fabrication shown in FIG. 2a;

FIG. 2e illustrates an isometric view of another embodiment of the present invention at the stage of fabrication shown in FIG. 2a;

FIG. 3a illustrates a cross-section of the present invention at a stage of fabrication subsequent to FIG. 2a;

FIG. 3b illustrates a cross-section of the present invention at a stage of fabrication subsequent to FIG. 3a;

FIG. 4 illustrates a cross-section of the present invention at a stage of fabrication subsequent to FIG. 3b;

FIG. 5 illustrates a cross-section of a pixel employing the present invention;

FIG. 6 is a block diagram of an imager device employing the present invention; and

FIG. 7 is a block diagram of a processor system employing a pixel constructed on a substrate fabricated in accordance with an embodiment of the present invention.

### DETAILED DESCRIPTION OF THE INVENTION

In the following detailed description, reference is made to various specific exemplary embodiments in which the invention may be practiced. These embodiments are described with sufficient detail to enable those skilled in the art to practice the invention, and it is to be understood that other embodiments may be employed, and that structural, logical, and electrical changes may be made.

The term “substrate” used in the following description may include any semiconductor-based structure that has a semiconductor surface. For the purposes of simplification, a substrate will be described herein as a silicon substrate; however, other semiconductor substrates may also be used.

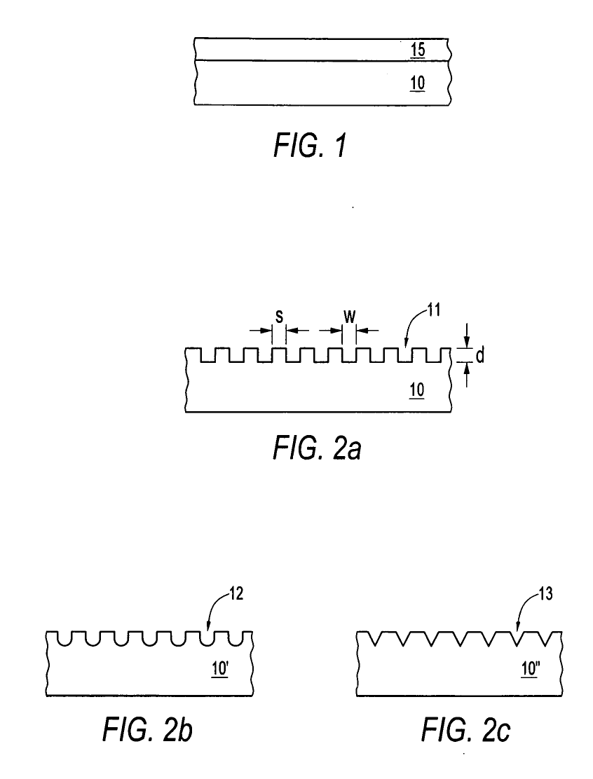

The invention discloses a substrate, system and method for creating buried dielectric structures for improving imager performance without the drawbacks of crystal defects and imager performance degradation, and at relatively low cost. Referring now to the drawings, FIG. 1 illustrates a cross-section of a semiconductor substrate 10 conventionally used in imager device fabrication. As described above, in conventional imager fabrication, silicon substrate 10 is a thin layer of silicon upon which an epitaxial silicon layer is formed and imager formation is conducted on the epitaxial layer. The present invention, on the other hand, utilizes a processed substrate structure as described below.

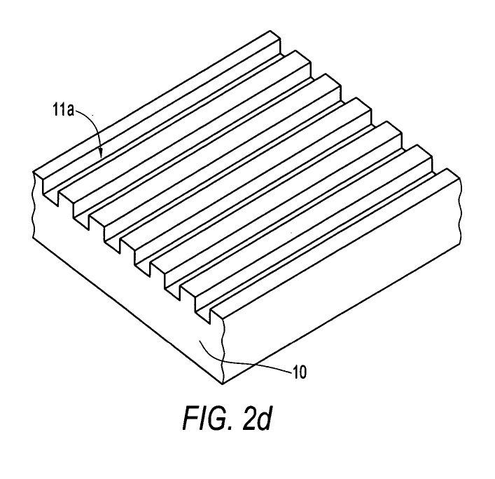

The invention is now described with reference to FIGS. 2a through 7. FIG. 2a illustrates a cross-section of substrate 10 at an initial stage of formation. Rectangular-shaped recesses 11 are formed in the substrate 10 shown in FIG. 1b. The recesses 11 may have a minimum depth d of about 20 nm and a width w corresponding to a subwavelength of visible light. The recesses 11 may be formed by any known method. Making the depth and width of the recesses less than the wavelength of visible light helps with light reflection as will be explained in greater detail below. The recesses 11 may be spaced apart by a space s that is at least one-tenth of the width of each recess 11, but less than ten times the width of each recess 11 to obtain good quality of silicon epi-growth.

The recesses may be formed in either as trenches, as shown in FIG. 2d, or as isolated recesses, as shown in FIG. 2e. FIG. 2d is an isometric view of substrate 10 having rectangular-shaped recesses 11a in a trench formation. The recesses 11a in trench formation may be arranged in a linear pattern. FIG. 2e is an isometric view of substrate 10 having rectangular-shaped recesses 11b in a isolated recess formation. When isolated recesses are used, the term “width of the recesses” refers to both width and length of the recesses. While FIG. 2e illustrates the recesses 11b formed in a checkerboard pattern, the recesses 11b may be in other patterns as well.

The recesses may also be formed in different shapes as shown, for example, in FIGS. 2b and 2c. FIG. 2b illustrates a cross-section of a substrate 10′ having recesses 12 with a curved bottom. FIG. 2c illustrates a cross-section of a substrate 10″ having recesses 13 with a triangular bottom. For ease of illustration, the subsequent process steps are described with respect to trenches having a rectangular formation, such as recesses 11 illustrated in FIG. 2a. However, as noted, the invention is not limited to a trench recess having a rectangular shape.

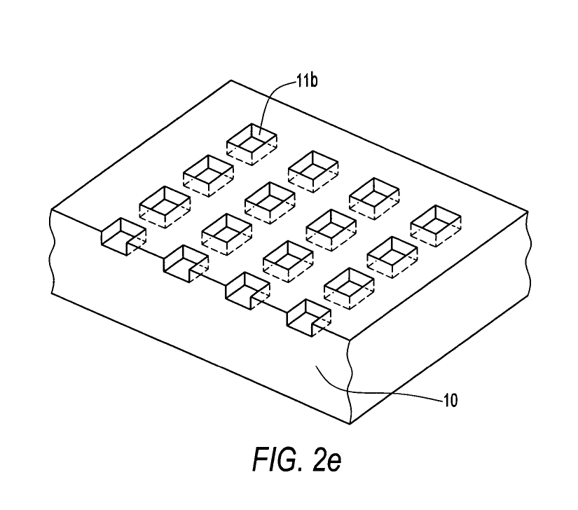

FIG. 3 illustrates a cross-section of substrate 10 at a stage of fabrication subsequent to FIG. 2a. A dielectric material is deposited in the recesses 11, forming a dielectric layer 20 comprising a plurality of filled recesses 25. A PSG or BPSG may be used as a flowable oxide, but the flowable oxide must be carefully deposited since these have a high percentage of phosphorous and boron, which may dope the silicon as it diffuses out. A more preferable method is to form the layer using a spin-on dielectric with typical densification to create silicon oxide with very similar properties to thermally grown oxide. The same may be accomplished by densifying PECVD oxide or high density plasma oxide. It is then planarized by, for example, CMP to the level of the silicon substrate 10, as shown in FIG. 3a.

As shown in FIG. 3b, the dielectric material in the filled recesses 25 are then further recessed by about 500-1300 Å, preferably about 900 Å, in order to grow defect-free epitaxial silicon over the substrate 10, as shown in FIG. 3b. For example, if an oxide dielectric material is used, a 25:1 distilled water to HF wet etch may be used to recess the oxide to the desired depth with good control and high selectivity to silicon.

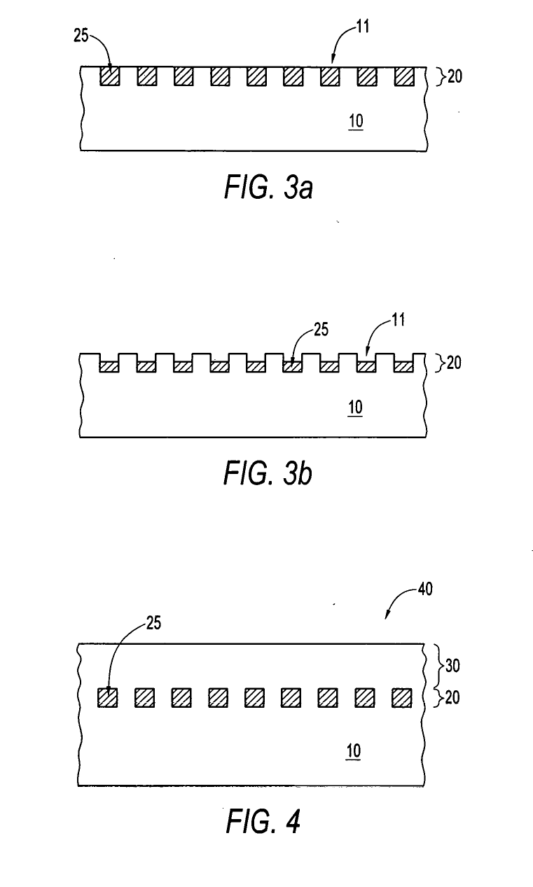

FIG. 4 illustrates a cross-section of substrate 10 at a stage of fabrication subsequent to FIG. 3b. An epitaxial layer of silicon 30 is grown over the surface of the substrate 10, burying the dielectric layer 20 (referred to hereinafter as the “buried dielectric layer 20”). The resulting structure 40 is a novel substrate having a buried dielectric layer 20 comprising a plurality of dielectric-filled recesses, hereinafter referred to as pockets 25.

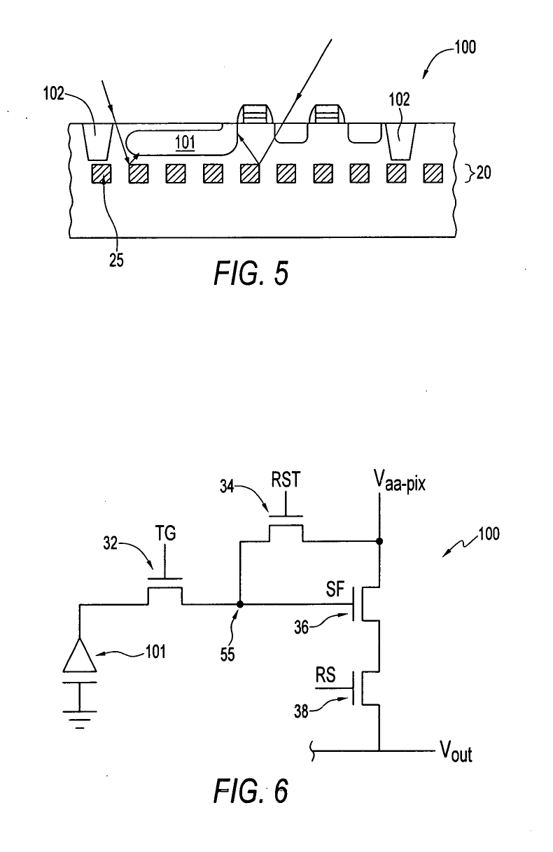

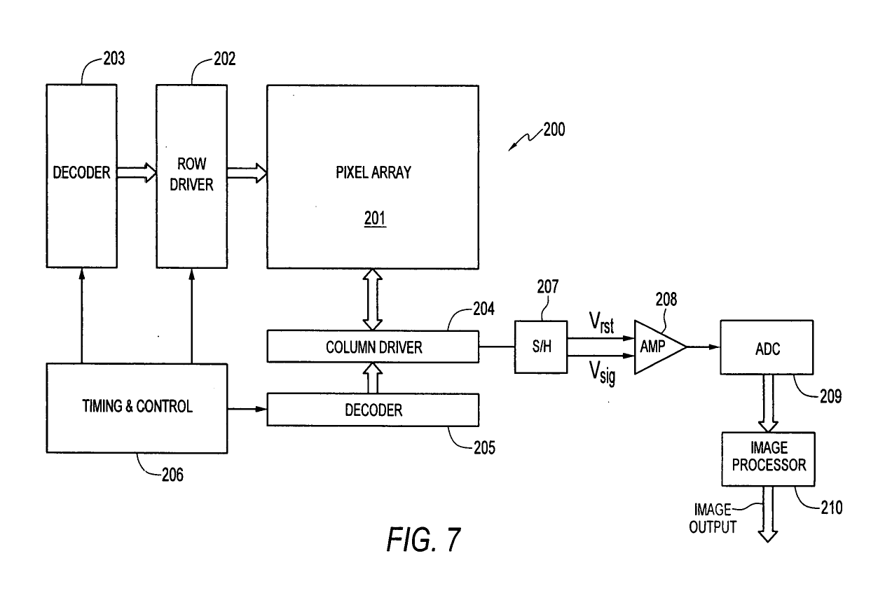

FIG. 5 illustrates a cross-section of a portion of an exemplary imager device pixel 100 formed on the EPI layer 30. The electrical schematic of an exemplary pixel cell is shown in FIG. 6, and includes a photosensor which may be a photodiode 101. As shown in FIG. 5, each pocket 25 is small enough that each photodiode 101 of each pixel subsequently formed on the substrate structure is formed to extend over several pockets 25.

The buried dielectric layer 20 provides some degree of electrical isolation to charge flow into the underlying substrate 10, without excluding the ability to use conventional isolation structures, such as the shallow trench isolation structures, to isolate pixels from each other in the EPI layer 30.

The sub-wavelength width and depth dimensions of the pockets 25 reduce loss of incident light and improve device sensitivity. Since the silicon has a different index of refraction than dielectric material filling the recesses, some incident light passing through the EPI layer 30 will be reflected at the dielectric material interface. Light reflected at the silicon-dielectric interface is redirected to the photosensor of the pixel (as shown by the arrows on FIG. 5).

Pixel cross-talk is also reduced since the buried dielectric layer 20 helps block pixel-to-pixel carrier mobility within underlying substrate 10.

The buried dielectric layer 20 also forms a pseudo-silicon-on-insulator (SOI) structure which provides a better substrate for overall transistor device performance.

FIG. 6 illustrates a schematic diagram of one exemplary CMOS four-transistor (4T) pixel cell 100 of FIG. 5, which may be found in the substrate of the invention. The four transistors include a transfer gate 32, reset gate 34, source follower transistor 36 and row select transistor 38. A photosensor, which may be a photodiode 101, 40 converts incident light into an electrical charge, which is accumulated during a charge integration period. A transfer gate 31 closes when activated by a transfer gate control signal TG and the floating diffusion region 55 receives accumulated charge from the photodiode 101. The floating diffusion region 55 is connected to the reset transistor 34 and the gate of the source follower transistor 36. The source follower transistor 36 outputs a signal proportional to the charge accumulated in the floating diffusion region 55 when the row select transistor 38 is turned on. The reset transistor 34 resets the floating diffusion region 55, when activated by a reset control signal RST, to a known potential prior to transfer of charge from the photosensor 40. The photosensor may be a photodiode 101, a photogate, or a photoconductor. If a photodiode 101 is employed, the photodiode may be formed below a surface of the substrate and may be a buried PNP photodiode, buried NPN photodiode, a buried PN photodiode, or a buried NP photodiode, among others.

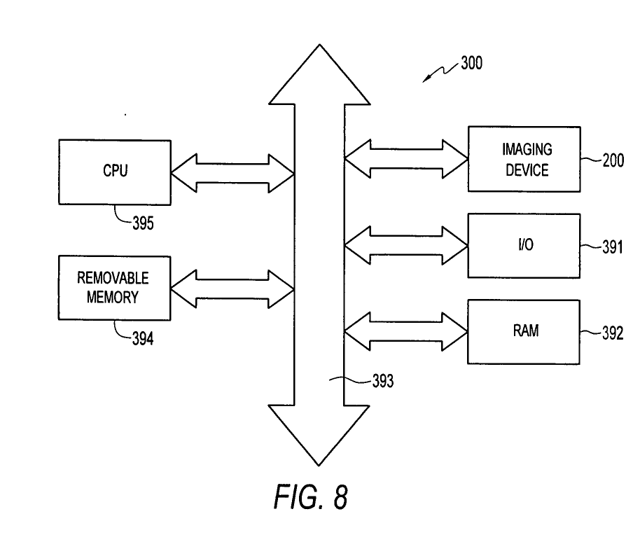

FIG. 7 illustrates a simplified block diagram of a CMOS imager device 200 having a pixel array 201 with each pixel cell being constructed on a substrate (e.g., structure 40) as described above. Pixel array 201 comprises a plurality of pixel cells arranged in a predetermined number of columns and rows. The row lines are selectively activated by the row driver 202 in response to row address decoder 203 and the column select lines are selectively activated by the column driver 204 in response to column address decoder 205. Thus, a row and column address is provided for each pixel cell.

The CMOS imager 200 is operated by a timing and control circuit 206, which controls decoders 203, 205 for selecting the appropriate row and column lines for pixel cell readout, and row and column driver circuitry 202, 204, which apply driving voltage to the drive transistors of the selected row and column lines. The pixel signals, which typically include a pixel cell reset signal Vrst and a pixel image signal Vsig for each pixel are read by sample and hold circuitry 207 associated with the column driver 204. A differential signal Vrst-Vsig is produced for each pixel, which is amplified by an amplifier 208 and digitized by analog-to-digital converter 209. The analog to digital converter 209 converts the analog pixel signals to digital signals, which are fed to an image processor 210 to form a digital image.

FIG. 8 shows in simplified form a typical processor system 300 modified to include an imaging device 200 (FIG. 6) employing a pixel cell having a substrate structure 40 constructed in accordance with the present invention. The processor system 300 is exemplary of a system having digital circuits that could include image sensor devices. Without being limiting, such a system could include a computer system, still or video camera system, scanner, machine vision, vehicle navigation, video phone, surveillance system, auto focus system, star tracker system, motion detection system, image stabilization system, and other systems employing an imaging device.

The processor system 300, for example a camera system, generally comprises a central processing unit (CPU) 395, such as a microprocessor, that communicates with an input/output (I/O) device 391 over a bus 393. Imaging device 200 also communicates with the CPU 395 over bus 393. The system 300 also includes random access memory (RAM) 392 and can include removable memory 394, such as flash memory, which also communicate with CPU 395 over the bus 393. Imaging device 200 may be combined with a processor, such as a CPU, digital signal processor, or microprocessor, with or without memory storage on a single integrated circuit or on a different chip than the processor.

While the invention has been described in the context of use of the substrate for fabrication of an imager device, the invention is not so limited and may be used for the fabrication of other circuits and devices. In addition, although an exemplary imaging device which may use the invention has been described and illustrated, the substrate of the invention may be used with other imaging devices employing other pixel architectures that are described and illustrated herein.

Furthermore, although the invention has been described and illustrated with specific processing steps including an HF wet etch, it should be noted that other processes for recessing the dielectric material within the recesses in the silicon are also contemplated. For example, a mask used to etch the recesses or cavities in the silicon may be left on the silicon such that it also serves as a mask during the dielectric recessing processes.

The above description and drawings are only to be considered illustrative of exemplary embodiments, which achieve the features and advantages of the invention. Modification and substitutions to specific process conditions and structures can be made without departing from the spirit and scope of the invention. Accordingly, the invention is not to be considered as being limited by the foregoing description and drawings, but is only limited by the scope of the appended claims.

What is claimed as new and desired to be protected by Letters Patent of the United States is:

1. An integrated circuit substrate comprising:
a semiconductor material base layer;
a buried layer, comprising a pattern of recesses filled with dielectric material in said semiconductor material; and
a semiconductor material layer over said buried layer.

2. The substrate of claim 1, wherein said buried layer is arranged to reflect incident light into said semiconductor material layer provided over said buried layer.

3. The substrate of claim 1, wherein said semiconductor material layer over said buried layer is epitaxial silicon.

4. The substrate of claim 1, wherein said semiconductor material base layer is formed of silicon.

5. The substrate of claim 1, wherein said pattern is a linear trench pattern.

6. The substrate of claim 1, wherein said pattern is a checkerboard pattern of isolated recesses.

7. The substrate of claim 1, wherein said filled recesses have a minimum depth of about 20 nm.

8. The substrate of claim 1, wherein each of said plurality of filled recesses has a subwavelength width.

9. The substrate of claim 1, wherein a space between two of said filled recesses is in the range of one-tenth of the width of each filled recess to ten times the width of each filled recess.

10. The substrate of claim 1, wherein said plurality of filled recesses have a rectangular cross-section.

11. The substrate of claim 1, wherein said plurality of filled recesses have a triangular cross-section.

12. The substrate of claim 1, wherein said plurality of filled recesses have a curved cross-section.

13. An imager system comprising:
a processor; and
an imager device comprising:
a pixel array fabricated on a substrate, said substrate comprising:
a silicon layer; and
a plurality of pockets filled with dielectric material which are entirely embedded in a horizontal layer within said silicon substrate.

14. The system of claim 13, wherein each said pixel of said array comprises a photodiode formed in said substrate above said pockets, and wherein said plurality of pockets is arranged to reflect incident light to said photodiode formed.

15. The system of claim 14, wherein said substrate above said plurality of pockets comprises an epitaxial silicon layer.

16. The system of claim 13, wherein said plurality of pockets have a minimum depth of about 20 nm has a subwavelength width.

17. The system of claim 13, wherein a space between two of said pockets is at least one-tenth of the width of each pocket and less than the width of each filled recess.

18. The system of claim 13, wherein said pockets have a rectangular cross-section.

19. The system of claim 13, wherein said pockets have a triangular cross-section.

20. The system of claim 13, wherein said pockets have a curved cross-section.

21. A method of forming a substrate for an imager pixel comprising:
providing a semiconductor base;
forming a plurality of recesses in a top surface of said silicon base;
filling said plurality of recesses with a dielectric material;
recessing said dielectric material; and
forming a top semiconductor layer over a top surface of said semiconductor base and said plurality of recesses.

22. The method of claim 21, wherein the step of providing a semiconductor base comprises providing a silicon base.

23. The method of claim 22, wherein the step of forming a top semiconductor layer comprises growing an epitaxial silicon layer.

24. The method of claim 21, wherein said step of forming a plurality of recesses comprises forming a plurality of trenches.

25. The method of claim 24, wherein said step of forming a plurality of recess further comprises forming said plurality recesses having a rectangular cross-section.

26. The method of claim 24, wherein said step of forming a plurality of recesses comprises forming said plurality of recesses having a triangular cross-section.

27. The method of claim 24, wherein said step of forming a plurality of recesses comprises forming said plurality of recesses having a curved cross-section.

28. The method of claim 21, wherein said step of forming a plurality of recesses comprises forming a plurality of isolated cavities.

29. The method of claim 28, wherein said step of forming a plurality of recesses further comprises forming said plurality recesses having a rectangular cross-section.

30. The method of claim 28, wherein said step of forming a plurality of recesses comprises forming said plurality of recesses triangular cross-section.

31. The method of claim 28, wherein said step of forming a plurality of recesses comprises forming said plurality of recesses having a curved cross-section.

32. The method of claim 21, wherein said step of forming a plurality of recesses comprises spacing apart said recesses by a distance comprising at least one-tenth of a width of each of said plurality of recesses and less than ten times the width of each of said plurality of recesses.

33. The method of claim 21, wherein said step of filling said plurality of recesses comprises depositing a flowable oxide over said top surface of said semiconductor base layer and said recesses.

34. The method of claim 21, wherein said step of filling said plurality of recesses comprises a spin-on-dielectric process.

35. The method of claim 21, wherein said step of filling said plurality of recesses comprises a chemical vapor deposition process.

36. The method of claim 21, further comprising planarizing to said top surface of said semiconductor base layer after filling said plurality of recesses.

37. The method of claim 36, wherein said planarizing step comprises chemical mechanical polishing.

38. The method of claim 21, wherein said recessing step is performed to a depth in the range of about 500 Å to about 1300 Å.

39. The method of claim 38, wherein said recessing step is performed to a depth of about 900 Å.

40. A method of forming an imager pixel array comprising:
forming a plurality of recesses in a top surface of a semiconductor substrate;
filling said plurality of recesses with a dielectric material;
removing a portion of said dielectric material from said plurality of recesses;
providing a top semiconductor layer over said top surface of said semiconductor substrate; and
forming a pixel array on said top semiconductor layer.

41. The method of claim 40, wherein said plurality of recesses is formed on a silicon substrate.

42. The method of claim 41, wherein top semiconductor layer is provided by growing an epitaxial silicon layer over said top surface of said silicon substrate and over said recesses.

43. The method of claim 42, wherein said plurality of recesses are spaced at a distance of at least one tenth of a width of each of said recesses and no greater than ten times the width of each of said plurality of trenches.
